(19) United States
(12) Patent Application Publication
(10) Pub. No.: US 2020/0091050 A1
(43) Pub. Date: Mar. 19, 2020

(54) Package Substrate and Method for Manufacturing Package Substrate

(71) Applicant: Tatsuta Electric Wire & Cable Co., Ltd., Osaka (JP)

(72) Inventor: Norihiro YAMAGUCHI, Kyoto (JP)

(21) Appl. No.: 16/464,271

(22) PCT Filed: Nov. 13, 2017
(86) PCT No.: PCT/JP2017/040697

§ 371 Date: May 26, 2019

(30) Foreign Application Priority Data
Dec. 19, 2016 (JP) 2016-245611

(51) Int. Cl. H01L 23/498; H01L 25/065; H01L 21/52; H01L 21/48

(52) U.S. Cl. CPC H01L 23/49811; H01L 21/4867; H01L 21/52; H01L 25/0657

(57) ABSTRACT

The present invention provides a package substrate in which metal pins capable of providing an electrical connection are disposed without tilting, and a method of producing the package substrate. The present invention provides a package substrate including: a substrate; and an electrode disposed on a surface of the substrate, wherein a metal pin is disposed on the electrode via a cured product of a conductive paste containing a metal powder and a thermosetting resin, and the metal powder contains a low-melting point metal and a high-melting point metal having a melting point higher than that of the low-melting point metal.

### CROSS-REFERENCE TO RELATED APPLICATIONS

This application is the U.S. National Stage of PCT application PCT/JP2017/040697 filed Nov. 13, 2017, the priority benefit of which is claimed and the contents of which are incorporated by reference. That PCT application, in turn, is based on Japanese application JP 2016-245611 filed Dec. 19, 2016, the priority benefit of which is claimed and the contents of which are incorporated by reference.

### TECHNICAL FIELD

The present invention relates to a package substrate and a method of producing the package substrate.

### BACKGROUND ART

Along with demands for integrated circuits with a higher capacity, higher speed, and lower power consumption, recent demands also include smaller and thinner semiconductor packages. In order to provide smaller and thinner semiconductor packages, three-dimensional packages such as a Package-on-Package (PoP) structure have been suggested in which different package substrates such as a logic package substrate and a memory package substrate are stacked on each other.

The basic PoP structure is a stack of multiple package substrates each including electrodes on its surface via solder balls between the package substrates. In the PoP structure, the package substrates are electrically connected to each other via the solder balls.

As an example of such a PoP structure, Patent Literature 1 discloses a stacked semiconductor package described below.

Specifically, Patent Literature 1 discloses a stacked semiconductor package including: multiple first package substrates each having a semiconductor device mounting region, which are stacked on each other via stacking solder balls; a second package substrate having multi-stage recessed parts in size corresponding to the multiple first package substrates, arranged to cover the multiple first package substrates such that the multiple first package substrates are housed in the multi-stage recessed parts, and including reference potential wires electrically connectable to the respective multiple first package substrates via connecting solder balls; and mounting solder balls disposed on the underside of the lowest first package substrate among the multiple first package substrates, and also disposed on lower ends of the second package substrate, wherein the multiple first package substrates are electrically connected to the reference potential wires at stages corresponding to respective the multi-stage recessed parts stages or bottom surfaces of the multi-stage recessed parts.

The stacked semiconductor package disclosed in Patent Literature 1 uses solder balls for electrical connection between the package substrates.

The size of the package substrate may be further reduced by further densely disposing electrodes on the surface of the package substrate. Densely disposing the electrodes requires densely disposing the solder balls. At the same time, a certain space is required between the solder balls in order to prevent a short circuit. The solder balls are substantially spherical, and the sphere is a shape that is disadvantageous for filling the space. In other words, despite attempts, the solder balls cannot be sufficiently densely disposed due to shape limitations.

Thus, another attempt was made to use columnar metal pins as a means to electrically connect package substrates to each other.

Patent Literature 2 discloses a method in which conductive posts (columnar metal pins) are disposed on a first substrate with a solder paste and the conductive posts are then connected to a second substrate with a solder paste, whereby the first substrate and the second substrate are electrically connected to each other.

### CITATION LIST

### Patent Literature

Patent Literature 1: JP 2012-160693 A

Patent Literature 2: JP 2016-48728 A

### SUMMARY OF INVENTION

### Technical Problem

In Patent Literature 2, when disposing the conductive posts on the first substrate with the solder paste, first, the solder paste is melted by heating and then solidified by cooling, whereby the conductive posts are fixed to the first substrate.

When the conductive posts are fixed to the first substrate with the solder paste as described above, unfortunately, the conductive posts may tilt by their own weight or the like because the solder paste has too low a viscosity during melting of the solder paste, or the conductive posts may tilt by changes in the surface tension of the solder paste during melting of the solder paste.

The present invention was made to solve the above problems, and aims to provide a package substrate in which metal pins capable of providing electrical connection are disposed without tilting, and a method of producing the package substrate.

### Solution to Problem

As a result of extensive studies to solve the above problems, the present inventor found that it is possible to dispose metal pins without tilting on a package substrate by using a conductive paste containing a low-melting point metal, a high-melting point metal, and a thermosetting resin as a means to fix the metal pins to the package substrate. The present invention was thus completed.

Specifically, the present invention provides a package substrate including: a substrate; and an electrode disposed on a surface of the substrate, wherein a metal pin is disposed on the electrode via a cured product of a conductive paste containing a metal powder and a thermosetting resin, and the metal powder contains a low-melting point metal and a high-melting point metal having a melting point higher than that of the low-melting point metal.

The package substrate of the present invention includes metal pins as a means to connect package substrates to each other. The metal pins are substantially columnar, and thus can be more densely disposed than substantially spherical solder balls used as a means to connect package substrates to each other. Thus, the package substrate of the present invention can be made smaller, and a PoP structure including a stack of the package substrates of the present invention can also be made smaller and thinner.

In the package substrate of the present invention, the metal pin is disposed on the electrode via a cured product of a conductive paste. In other words, the metal pin is fixed to the electrode with a conductive paste in producing the package substrate of the present invention.

When a metal pin is fixed to an electrode with solder, for example, the metal pin may tilt due to too low a viscosity of the solder or by changes in the surface tension of the solder during melting of the solder.

In contrast, the conductive paste cures when heated because it contains a thermosetting resin. Thus, the metal pin is less likely to tilt when fixed to the electrode with the conductive paste than when fixed with the solder. That is, tilting is suppressed in the package substrate of the present invention.

In the package substrate of the present invention, the metal powder contains a low-melting point metal and a high-melting point metal having a melting point higher than that of the low-melting point metal.

When the metal powder contains a low-melting point metal, heating the conductive paste softens the low-melting point metal and temporarily reduces the viscosity of the conductive paste. Subsequently, the thermosetting resin in the conductive paste cures, whereby a cured product of the conductive paste is obtained.

In producing the package substrate of the present invention, use of a low-melting point metal allows the conductive paste to come into contact with the metal pins without a gap when the viscosity of the conductive paste is temporarily reduced upon heating of the conductive paste. Subsequently, the conductive paste cures, whereby the metal pins are rigidly fixed.

In other words, in the package substrate in which the metal powder contains a low-melting point metal, the metal pins are rigidly fixed and disposed on the electrodes.

In addition, when the metal powder contains a high-melting point metal, it can improve the conductivity of the conductive paste.

In the package substrate of the present invention, preferably, an alloy of the low-melting point metal and the metal pin is present between the cured product of the conductive paste and the metal pin.

That “an alloy of the low-melting point metal and the metal pin is present between the cured product of the conductive paste and the metal pin” means that a part of the cured product of the conductive paste is integrated with a part of the metal pin. Thus, in such a package substrate, the metal pins are rigidly fixed and disposed on the electrodes.

Further, such an alloy has excellent heat resistance and thus can also improve the heat resistance of the package substrate.

As used herein, an alloy may be a mixture of a low-melting point metal element and an element constituting the metal pins, or an intermetallic compound of these elements.

In the package substrate of the present invention, the low-melting point metal preferably has a melting point of 180° C. or lower.

When the melting point of the low-melting point metal is higher than 180° C., the thermosetting resin tends to start curing before the viscosity of the conductive paste is temporarily reduced upon heating of the conductive paste, or the temperature range in which the viscosity of the conductive paste is reduced tends to become narrow. Thus, the metal pins are less likely to be rigidly fixed to the electrodes in the package substrate.

In the package substrate of the present invention, the low-melting point metal preferably includes at least one selected from the group consisting of indium, tin, lead, and bismuth.

These metals each have a suitable melting point and suitable conductivity as low-melting point metals.

In the package substrate of the present invention, the melting point of the high-melting point metal is preferably 800° C. or higher.

In the package substrate of the present invention, the high-melting point metal preferably includes at least one selected from the group consisting of copper, silver, gold, nickel, silver-coated copper, and silver-coated copper alloy.

These metals have excellent conductivity. Thus, these metals can improve conductivity between the metal pins and the electrodes in the package substrate.

These high-melting point metals form alloys with the low-melting point metals and thus can provide continuous conductive paths.

When the cured product of the conductive paste contains only a high-melting point metal but not a low-melting point metal as a metal powder, a conductive path is only formed by point contact between the high-melting point metals and by point contact between the high-melting point metal and the metal pins. This makes it difficult to keep the connection resistance low between the metal pins and the package substrate.

In the package substrate of the present invention, the metal pin preferably contains at least one selected from the group consisting of copper, silver, gold, and nickel.

These metals have excellent conductivity. Thus, these metals can suitably electrically connect the package substrates to each other.

The present invention provides a method of producing the package substrate, including: a substrate preparation step of preparing a substrate including an electrode disposed on a surface thereof; a printing step of printing a conductive paste containing a metal powder and a thermosetting resin on the electrode; a metal pin positioning step of positioning a metal pin on the conductive paste; and a metal pin disposing step of disposing the metal pin on the electrode via a cured product of the conductive paste obtained by heating the conductive paste to soften and then cure the conductive paste, wherein the metal powder contains a low-melting point metal and a high-melting point metal having a melting point higher than that of the low-melting point metal.

The present invention provides a method of producing the package substrate, including: a substrate preparation step of preparing a substrate including an electrode disposed on a surface thereof; a conductive paste attaching step of attaching a conductive paste containing a metal powder and a thermosetting resin to an end of a metal pin; a metal pin positioning step of positioning the metal pin on the electrode by contact with the conductive paste; and a metal pin disposing step of disposing the metal pin on the electrode via a cured product of the conductive paste obtained by heating the conductive paste to soften and then cure the conductive paste, wherein the metal powder contains a low-melting point metal and a high-melting point metal having a melting point higher than that of the low-melting point metal.

### Advantageous Effects of Invention

The package substrate of the present invention includes the metal pins as a means to connect package substrates to each other. The metal pins are substantially columnar, and thus can be sufficiently densely disposed. Thus, the package substrate of the present invention can be made smaller, and a PoP structure including a stack of the package substrates of the present invention can also be made smaller and thinner.

### BRIEF DESCRIPTION OF DRAWINGS

FIG. 1A is a schematic side view showing an exemplary package substrate of the present invention.

FIG. 1B is a top view of FIG. 1A.

FIG. 2A is a schematic side view showing an exemplary package substrate with solder balls disposed thereon. FIG. 2B is a top view of FIG. 2A.

FIG. 3A is a schematic side view showing an exemplary PoP structure including the package substrate shown in FIG. 1A.

FIG. 3B is a schematic side view showing an exemplary PoP structure including the package substrate shown in FIG. 2A.

FIG. 4 is an enlarged sectional view showing an exemplary relationship between an electrode on the package substrate, a cured product of a conductive paste, and a metal pin of the present invention.

FIG. 5 is a schematic view showing a substrate preparation step included in the method of producing the package substrate of the present invention.

FIG. 6 is a schematic view showing a printing step included in the method of producing the package substrate of the present invention.

FIG. 7 is a schematic view showing a metal pin positioning step included in the method of producing the package substrate of the present invention.

FIGS. 8A and 8B are schematic views showing a metal pin disposing step included in the method of producing the package substrate of the present invention.

FIGS. 9A and 9B are schematic views showing an exemplary method of disposing metal pins with solder on the electrodes disposed on the surface of the package substrate.

FIG. 10 is a schematic view showing a conductive paste attaching step included in the method of producing the package substrate of the present invention.

FIG. 11 is a schematic view showing a metal pin positioning step included in the method of producing the package substrate of the present invention.

FIG. 12A is an SEM image of a boundary between a cured product of a conductive paste and a metal pin on a package substrate according to Example 1.

FIG. 12B is a mapping image showing the distribution of tin on the boundary between the cured product of the conductive paste and the metal pin on the package substrate according to Example 1.

FIG. 12C is a mapping image showing the distribution of bismuth on the boundary between the cured product of the conductive paste and the metal pin on the package substrate according to Example 1.

FIG. 12D is a mapping image showing the distribution of copper on the boundary between the cured product of the conductive paste and the metal pin on the package substrate according to Example 1.

FIG. 12E is a mapping image showing the distribution of silver on the boundary between the cured product of the conductive paste and the metal pin on the package substrate according to Example 1.

### DESCRIPTION OF EMBODIMENTS

The package substrate of the present invention may include any structure as long as it includes a substrate and an electrode disposed on a surface of the substrate, wherein a metal pin is disposed on the electrode via a cured product of a conductive paste containing a metal powder and a thermosetting resin, and the metal powder contains a low-melting point metal and a high-melting point metal having a melting point higher than that of the low-melting point metal.

An exemplary package substrate of the present invention is specifically described below. Yet, the present invention is not limited to the following embodiments, and can be appropriately modified without changing the gist of the present invention.

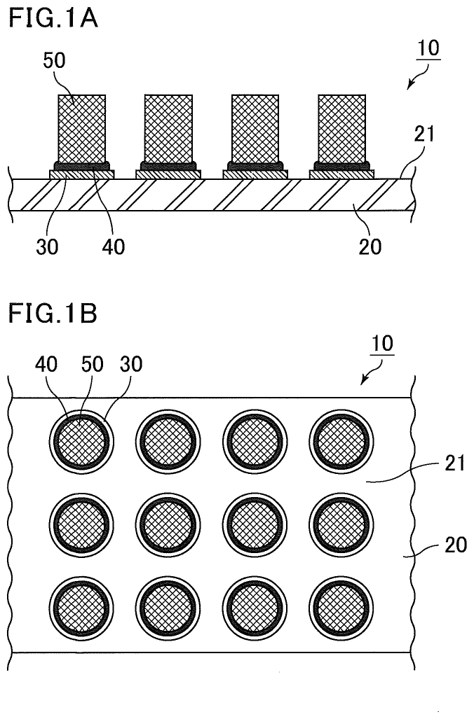

FIG. 1A is a schematic side view showing an exemplary package substrate of the present invention.

FIG. 1B is a top view of FIG. 1A.

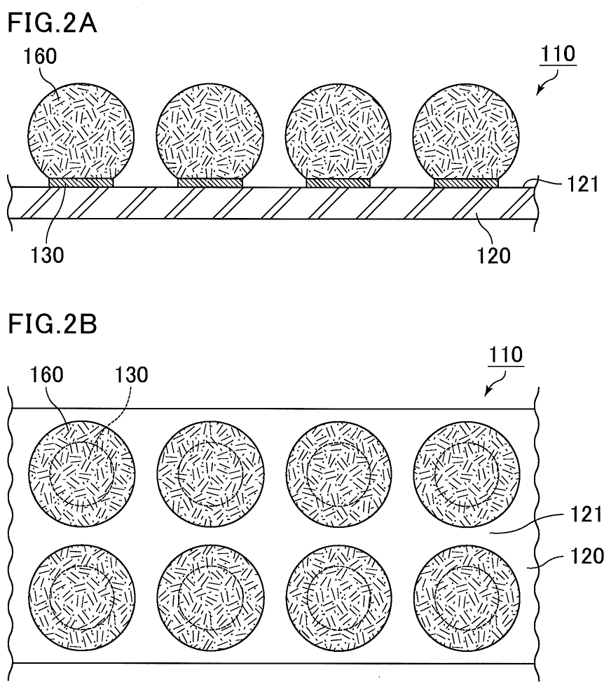

FIG. 2A is a schematic side view showing an exemplary package substrate with solder balls disposed thereon. FIG. 2B is a top view of FIG. 2A.

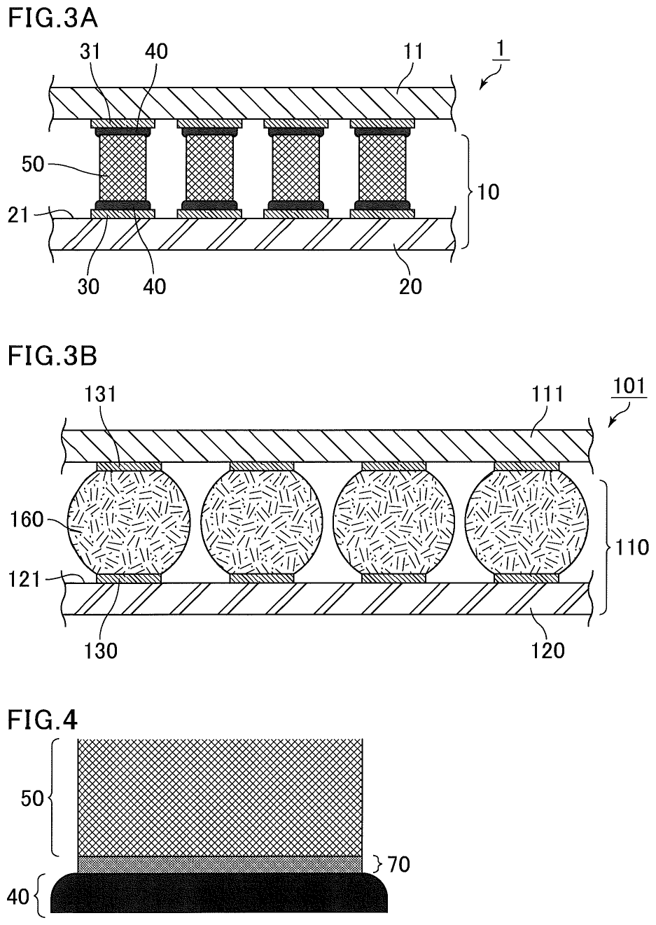

FIG. 3A is a schematic side view showing an exemplary PoP structure including the package substrate shown in FIG. 1A.

FIG. 3B is a schematic side view showing an exemplary PoP structure including the package substrate shown in FIG. 2A.

A package substrate 10 shown in FIG. 1A is a package substrate including a substrate 20 and electrodes 30 disposed on a surface 21 of the substrate 20.

Metal pins 50 are disposed on the electrodes 30 via a cured product 40 of a conductive paste containing a metal powder and a thermosetting resin.

In contrast, a package substrate 110 shown in FIG. 2A is a package substrate including a substrate 120 and electrodes 130 disposed on a surface 121 of the substrate 120.

Solder balls 160 are disposed on the electrodes 130.

The metal pins 50 are substantially cylindrical as shown in FIGS. 1A and 1B, whereas the solder balls 160 are substantially spherical as shown in FIGS. 2A and 2B.

In FIGS. 1A and 1B and FIGS. 2A and 2B, the electrodes 30 and the electrodes 130 have the same size. The metal pins 50 and the solder balls 160 have sizes required to produce a PoP structure using these package substrates.

In the top view of the package substrate 110, as shown in FIG. 2B, the solder ball 160 has a larger outline than the electrode 130 disposed on the substrate 120. Contact between the solder balls 160 causes a short circuit, so that the electrodes 130 are disposed in the package substrate 110 to avoid contact between the solder balls 160. Thus, the interval between the electrodes 130 is wide in the package substrate 110.

In the top view of the package substrate 10, as shown in FIG. 1B, the metal pin 50 has a smaller outline than the electrode 30 disposed on the substrate 20. Thus, the electrodes 30 can be disposed without concern for contact between the metal pins 50 in the package substrate 10. Thus, the interval between the electrodes 30 is narrow in the package substrate 10.

In other words, when three-dimensional objects are densely disposed on the package substrate, substantially columnar three-dimensional objects are more advantageous than substantially spherical three-dimensional objects.

For this reason, the metal pins 50 can be more densely disposed than the solder balls 160 on the package substrate. Thus, the package substrate 10 can be made smaller than the package substrate 110.

As shown in FIG. 3A, another package substrate 11 is stacked on the package substrate 10, thus providing a PoP structure 1. Here, the electrode 31 disposed on the underside of the package substrate 11 is connected to the top of the metal pin 50 via the cured product 40 of the conductive paste.

As shown in FIG. 3B, another package substrate 111 is stacked on the package substrate 110, thus providing the PoP structure 101. Here, the electrode 131 disposed on the underside of the package substrate 110 is connected to the top of the solder ball 160.

A comparison between FIG. 3A and FIG. 3B shows that the PoP structure 1 further including the package substrate 11 stacked on the package substrate 10 is narrower and thinner than the PoP structure 101 including the package substrate 111 stacked on the package substrate 110.

The PoP structure 1 is narrower than the PoP structure 101 because the metal pins 50 are more easily densely disposed on the package substrate than the solder balls 160, as described above.

The PoP structure 1 is thinner than the PoP structure 101 because of the following reasons.

As shown in FIG. 2A, each solder ball 160 has a curved top surface. As shown in FIG. 3B, the electrode 131 disposed on the bottom of the package substrate 111 has a flat bottom surface.

The solder ball 160 is connected to the electrode 131 by melting the top surface of the solder ball 160, and the solder ball 160 that is slightly large is used so that the solder ball 160 can sufficiently cover the bottom surface of the electrode 131.

In contrast, as shown in FIG. 1A, each metal pin 50 has a flat top surface. As shown in FIG. 3A, the electrode 31 disposed on the bottom of the package substrate 11 has a flat bottom surface.

Further, the top surface of the metal pin 50 is connected to the bottom surface of the electrode 31 via the cured product 40 of the thermosetting resin.

In other words, in the PoP structure 1, the metal pins 50 do not need to be designed large, unlike the solder balls 160 which need to be designed large in consideration of melting of the top surfaces thereof.

Thus, the PoP structure 1 can be made thinner than the PoP structure 101.

For these reasons, the PoP structure 1 including a stack of the package substrates 10 can be made smaller and thinner with the use of the metal pins 50.

As described later, in the package substrate 10, the metal pins 50 are erected via the cured product 40 of the conductive paste, without tilting relative to the substrate 20. Thus, in the PoP structure 1 shown in FIG. 3A, solder may be used to connect the electrodes 31 disposed on the bottom of the package substrate 11 to the top of the metal pins 50.

In the package substrate 10, the metal pins 50 may have any shape as long as it has a substantially columnar shape. Examples of the shape include prisms such as substantially triangular prism, substantially quadrangular prism, and substantially hexagonal prism; substantially cylinder; and substantially elliptic cylinder.

Preferred among these are quadrangular prism and cylinder.

When each metal pin 50 has a quadrangular prismatic shape, its bottom surface preferably has a substantially rectangular shape with a length of 50 to 300 μm and a width of 50 to 300 μm.

When each metal pin 50 has a cylindrical shape, its bottom surface preferably has a substantially circular shape with a diameter of 50 to 200 μm, more preferably a substantially circular shape with a diameter of 70 to 150 μm.

When each metal pin 50 has a bottom surface having the size and shape described above, the metal pins 50 can be suitably densely disposed.

In the package substrate 10, the density of the metal pins 50 is preferably 100 to 500 pins per package, more preferably 300 to 400 pins per package. The pitch of the metal pins 50 is preferably 0.2 to 0.5 mm. The pitch of the metal pins 50 means the distance between two adjacent metal pins 50.

With the metal pins 50 densely disposed as described above, the package substrate 10 and the PoP structure 1 including a stack of the package substrates 10 can be made smaller.

The height of the metal pins 50 is not particularly limited, but it is preferably 50 to 500 μm.

When the height of the metal pins 50 is in the above range, the height of the PoP structure 1 including a stack of the package substrates 10 can be reduced.

In the package substrate 10, the metal pins preferably include at least one selected from the group consisting of copper, silver, gold, and nickel.

These metals each have excellent conductivity. Thus, these metals can suitably electrically connect the package substrates to each other.

In the package substrate 10, the metal pins 50 are disposed on the electrodes 30 via the cured product 40 of the conductive paste. In other words, in producing the package substrate 10, the metal pins 50 are fixed to the electrodes 30 with the conductive paste.

For example, when a metal pin is fixed to an electrode with solder, the metal pin may tilt due to too low a viscosity of the solder or by changes in the surface tension of the solder during melting of the solder.

In contrast, the conductive paste cures when heated because it contains a thermosetting resin. Thus, the metal pins are less likely to tilt when fixed to the electrodes with the conductive paste than when fixed with solder. That is, tilting of the metal pins 50 is suppressed in the package substrate 10.

In the package substrate 10, the cured product 40 of the conductive paste contains a cured thermosetting resin and a metal powder.

The cured thermosetting resin is not particularly limited, but a cured product of a resin such as acrylate resin, epoxy resin, phenolic resin, urethane resin, or silicone resin is preferred.

More specific examples of the thermosetting resin include bisphenol A epoxy resins, brominated epoxy resins, bisphenol F epoxy resins, novolac epoxy resins, alicyclic epoxy resins, glycidylamine epoxy resins, diglycidyl ether resins such as 1,6-hexanediol diglycidyl ether, heterocyclic epoxy resins, and aminophenol epoxy resins.

These thermosetting resins may be used alone or in combination of two or more thereof.

The curing temperature of the thermosetting resin before curing is preferably at least 10° C. higher than the melting point of the later-described low-melting point metal. The upper limit of the curing temperature is preferably 200° C.

When the curing temperature of the thermosetting resin is lower than the temperature mentioned above, the thermosetting resin starts curing before the low-melting point metal is sufficiently softened, making it difficult for the low-melting point metal to form an alloy with the metal pins.

The curing temperature of the thermosetting resin is preferably 160° C. to 180° C.

The metal powder contains a low-melting point metal and a high-melting point metal having a melting point higher than that of the low-melting point metal.

The metal powder is not particularly limited as long as it contains a low-melting point metal and a high-melting point metal. For example, the metal powder may be a mixture of low-melting point metal particles and high-melting point metal particles, may consist of integrated particles of a low-melting point metal and a high-melting point metal, or may be a mixture of low-melting point metal particles, high-melting point metal particles, and integrated particles of a low-melting point metal and a high-melting point metal.

When the metal powder contains a high-melting point metal, it can improve the conductivity of the conductive paste.

When the metal powder contains a low-melting point metal, heating the conductive paste softens the low-melting point metal and temporarily reduces the viscosity of the conductive paste. Subsequently, the thermosetting resin in the conductive paste cures, whereby a cured product of the conductive paste is obtained.

In producing the package substrate 10, use of a low-melting point metal allows the conductive paste to come into contact with the metal pins without a gap when the viscosity of the conductive paste is reduced temporarily upon heating of the conductive paste. Subsequently, the conductive paste cures, whereby the metal pins 50 are rigidly fixed.

In other words, in the package substrate in which the metal powder contains a low-melting point metal, the metal pins 50 are rigidly fixed and disposed on the electrodes 30.

When the conductive paste contains a low-melting point metal, an alloy is formed between the metal pins 50 and the low-melting point metal during curing of the conductive paste. This allows the metal pins 50 to be rigidly fixed to the electrodes 30, and can improve the conductivity of the conductive paste.

Further, such an alloy has excellent heat resistance and thus can also improve the heat resistance of the package substrate.

The case where such an alloy is present is described below with reference to the drawings.

FIG. 4 is an enlarged sectional view showing an exemplary relationship between an electrode on the package substrate, a cured product of a conductive paste, and a metal pin of the present invention.

As shown in FIG. 4, in the package substrate 10, an alloy 70 of a low-melting point metal and the metal pin 50 is present between the cured product 40 of the conductive paste and the metal pin 50.

In other words, at least a part of the metal pin 50 is integrated with a part of the conductive paste. Thus, in the package substrate 10, the metal pins 50 are rigidly fixed and disposed on the electrodes 30.

The alloy 70 may contain an element derived from a high-melting point metal.

Whether or not the alloy 70 is present between the cured product 40 of the conductive paste and the metal pin 50 can be observed by energy-dispersive X-ray spectroscopy (EDS).

Observation with EDS may be made using an energy-dispersive spectroscopy (JEOL Ltd., model number: JED-2300) mounted on a scanning electron microscope (JEOL Ltd., model number: JSM-7800F) under conditions at a magnification of 3000 times and an acceleration voltage of 3 to 15 kV.

In the package substrate 10, the low-melting point metal preferably has a melting point of 180° C. or lower, more preferably 60° C. to 180° C., still more preferably 120° C. to 145° C.

When the melting point of the low-melting point metal is higher than 180° C., curing of the thermosetting resin tends to start before the viscosity of the conductive paste is temporarily reduced when the conductive paste is heated, or the temperature range in which the viscosity of the conductive paste is reduced tends to become narrow. Thus, the metal pins 50 are less likely to be rigidly fixed to the electrodes 30 in the package substrate 10.

When the melting point of the low-melting point metal is lower than 60° C., the temperature at which the viscosity of the conductive paste reduces is so low that the metal pins 50 tend to tilt when fixed on the electrodes 30. In contrast, when the melting point of the low-melting point metal is 60° C. or higher, the metal pins 50 are less likely to tilt in the package substrate 10.

In the package substrate 10, the low-melting point metal preferably includes at least one selected from the group consisting of indium, tin, lead, and bismuth, with tin being more preferred.

These metals each have a suitable melting point and conductivity as low-melting point metals.

In the package substrate 10, the high-melting point metal preferably has a melting point of 800° C. or higher, more preferably 800° C. to 1500° C., still more preferably 900° C. to 1100° C.

The high-melting point metal preferably includes at least one selected from the group consisting of copper, silver, gold, nickel, silver-coated copper, and silver-coated copper alloy.

These metals each have excellent conductivity. Thus, the package substrate 10 can have higher conductivity between the metal pins 50 and the electrodes 30.

In the package substrate 10, when the metal powder contains the low-melting point metal and the high-melting point metal, the alloy 70 of the cured product 40 of the conductive paste and the metal pins 50 is preferably an alloy of tin and copper.

The weight ratio of the low-melting point metal and the high-melting point metal is not particularly limited, but the weight ratio of the low-melting point metal to the high-melting point metal is preferably 80:20 to 20:80.

When the weight ratio of the low-melting point metal to the high-melting point metal is higher than the above range, the conductive paste temporarily becomes so soft during curing of the conductive paste that the metal pins tend to tilt, in producing the package substrate of the present invention.

When the weight ratio of the low-melting point metal to the high-melting point metal is lower than the above range, the amount of alloy of the low-melting point metal and the metal pins tends to be small during curing of the conductive paste due to a small amount of the low-melting point metal, in producing the package substrate of the present invention. As a result, the metal pins tend to be less rigidly fixed.

In the package substrate 10, the metal powder content in the cured product 40 of the conductive paste is preferably 80 to 95% by weight.

When the metal powder content in the cured product of the conductive paste is less than 80% by weight, the package substrate tends to have high resistance.

When the metal powder content in the cured product of the conductive paste is more than 95% by weight, the conductive paste has poor printability due to high viscosity, in producing the package substrate of the present invention. As a result, the cured product of the conductive paste tends to have poor printing conditions.

In the package substrate 10, the substrate 20 may be made of any material. Examples include epoxy resin, BT resin (bismaleimide triazine), polyimide, fluorine resin, polyphenylene ether, liquid crystal polymer, phenolic resin, and ceramic.

In the package substrate 10, the electrode 30 may be made of any material. Examples include copper, tin, nickel, aluminum, gold, and silver.

The package substrate 10 preferably has a substantially rectangular shape with a length of 10 to 30 mm and a width of 10 to 50 mm.

In the package substrate of the present invention, solder balls may be disposed as needed.

In other words, in the package substrate of the present invention, the metal pins that are disposed via the cured product of the conductive paste containing a metal powder and a thermosetting resin may be used in combination with solder balls.

Next, a method of producing such a package substrate of the present invention is described with reference to the following two examples.

### (First Exemplary Method of Producing the Package Substrate of the Present Invention)

A first exemplary method of producing the package substrate of the present invention includes:

(1) a substrate preparation step of preparing a substrate including an electrode disposed on a surface thereof;
(2) a printing step of printing a conductive paste containing a metal powder and a thermosetting resin on the electrode;
(3) a metal pin positioning step of positioning a metal pin on the conductive paste; and
(4) a metal pin disposing step of disposing the metal pin on the electrode via a cured product of the conductive paste obtained by heating the conductive paste to soften and then cure the conductive paste.

Each step is described with reference to the drawings.

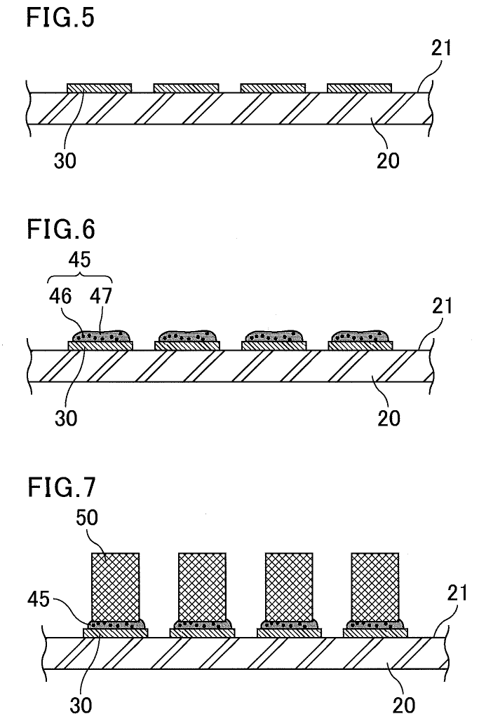

FIG. 5 is a schematic view showing a substrate preparation step included in the method of producing the package substrate of the present invention.

FIG. 6 is a schematic view showing a printing step included in the method of producing the package substrate of the present invention.

FIG. 7 is a schematic view showing a metal pin positioning step included in the method of producing the package substrate of the present invention.

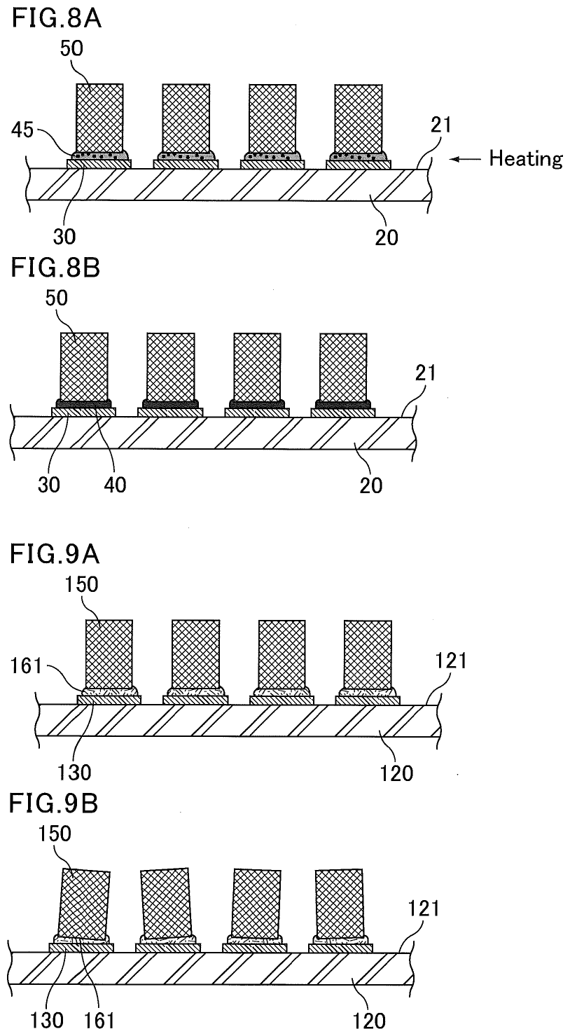

FIGS. 8A and 8B are schematic views showing a metal pin disposing step included in the method of producing the package substrate of the present invention.

### (1) Substrate Preparation Step

As shown in FIG. 5, first, the substrate 20 including the electrodes 30 disposed on the surface 21 is prepared.

Preferred materials of the substrate 20 and the electrode 30 are as described above for the package substrate of the present invention, and the descriptions thereof are thus omitted.

The substrate including the electrodes disposed on the surface thereof can be produced by a known method.

### (2) Printing Step

### (2-1) Preparation of Conductive Paste

In this step, first, a conductive paste is prepared.

The conductive paste can be prepared by mixing a metal powder with a thermosetting resin.

The weight ratio of the thermosetting resin to the metal powder is not particularly limited in the conductive paste to be prepared, but the weight ratio of the thermosetting resin to the metal powder is preferably 20:80 to 5:95.

In the conductive paste to be prepared, the metal powder contains a low-melting point metal and a high-melting point metal.

Preferred materials and properties of the thermosetting resin, the low-melting point metal, and the high-melting point metal in the conductive paste are as described above for the package substrate of the present invention, and the descriptions thereof are thus omitted.

In preparing the conductive paste, the conductive paste may be mixed with materials such as a curing agent, flux, a curing catalyst, a defoaming agent, a levelling agent, an organic solvent, and inorganic filler, in addition to the metal powder and the thermosetting resin.

Examples of the curing agent include 2-phenyl-4,5-dihydroxymethylimidazole, 2-phenylimidazole, 2-undecylimidazole, 2-heptadecylimidazole, 2-ethylimidazole, 2-phenylimidazole, 2-ethyl-4-methylimidazole, 1-cyanoethyl-2-undecylimidazole, and 1-cyanoethyl-2-undecylimidazolium trimellitate.

Examples of the flux include zinc chloride, lactic acid, citric acid, oleic acid, stearic acid, glutamic acid, benzoic acid, oxalic acid, glutamic acid hydrochloride, aniline hydrochloride, cetylpyridinium bromide, urea, hydroxyethyl laurylamine, polyethylene glycol laurylamine, oleylpropylenediamine, triethanolamine, glycerol, hydrazine, and rosin.

### (2-2) Printing of Conductive Paste

Next, as shown in FIG. 6, a conductive paste 45 containing a metal powder 46 and a thermosetting resin 47 is printed.

The printing method of the conductive paste 45 is not particularly limited, and a known method such as screen printing can be used.

### (3) Metal Pin Positioning Step

Next, as shown in FIG. 7, the metal pins 50 are positioned on the conductive paste 45.

The metal pins 50 are preferably positioned at a density of 300 to 400 pins per package.

With the metal pins 50 densely positioned as described above, it is possible to produce a smaller package substrate. A PoP structure including a stack of the produced package substrates can also be made smaller.

Preferred shapes and materials of the metal pins 50 are as described above for the package substrate of the present invention, and the descriptions thereof are thus omitted.

### (4) Metal Pin Disposing Step

Next, as shown in FIG. 8A, the cured product 40 of the conductive paste is obtained by heating the conductive paste 45 to soften and then cure the conductive paste 45. Thus, as shown in FIG. 8B, the metal pins 50 can be disposed on the electrodes 30 via the cured product 40 of the conductive paste.

The metal pins 50 are less likely to tilt when fixed to the electrodes 30 with the conductive paste 45 than when fixed with solder.

This principle is explained by comparison to the case where the metal pins are fixed to the electrodes with solder.

FIGS. 9A and 9B are schematic views showing an exemplary method of disposing metal pins with solder on the electrodes disposed on the surface of the package substrate.

As shown in FIG. 9A, when solder 161 is used to dispose metal pins 150 on the electrodes 130, first, the solder 161 is applied to the electrodes 130, and the metal pins 150 are positioned on the solder.

Next, as shown in FIG. 9B, the solder 161 is melted by heating, and the solder 161 is then solidified by cooling. Thus, the metal pins 150 are fixed to the electrodes 130.

In the case where the metal pins 150 are fixed to the electrodes 130 with the solder 161 as described above, the metal pins 150 tend to tilt due to too low a viscosity of the solder 161 or by changes in the surface tension of the solder 161 during melting of the solder, as shown in FIG. 9B. The solder 161 is solidified by cooling with the metal pins 150 in the tilting state. Thus, the metal pins 150 tend to be fixed to the electrodes 130 while tilting.

In contrast, in the case where the metal pins 50 are disposed on the electrodes 30 with the conductive paste 45 as shown in FIGS. 8A and 8B, the conductive paste 45 cures when heated because it contains the thermosetting resin 47. Thus, the metal pins 50 are less likely to tilt when fixed to the electrodes 30 with the conductive paste 45 than when fixed with solder.

Further, the heating temperature of the conductive paste 45 in the metal pin disposing step is preferably at least 10° C. higher than the melting point of the low-melting point metal. The upper limit of the heating temperature is preferably 200° C.

When the heating temperature is not at least 10° C. higher than the melting point of the low-melting point metal, the thermosetting resin 47 starts curing before the low-melting point metal is sufficiently softened, making it difficult for the low-melting point metal to form an alloy with the metal pins 50.

When the heating temperature is higher than 200° C., it tends to cause degradation of the metal powder in the cured product of the conductive paste 45, the cured thermosetting resin, and the metal pins.

In addition, since the conductive paste 45 contains a low-melting point metal and a high-melting point metal, heating the conductive paste 45 softens the low-melting point metal and temporarily reduces the viscosity of the conductive paste 45. This allows the conductive paste 45 to come into contact with the metal pins 50 without a gap.

Subsequently, the conductive paste 45 cures, whereby the metal pins 50 are rigidly fixed.

In other words, the metal pins 50 can be rigidly fixed to the electrodes 30 due to the presence of the low-melting point metal in the metal powder.

The minimum viscosity when the viscosity of the conductive paste 45 is temporarily reduced is preferably 40 to 200 Pa·s, more preferably 60 to 180 Pa·s.

The low-melting point metal forms an alloy with the metal pins 50 during curing of the conductive paste 45 due to the presence of the low-melting point metal in the metal powder. This allows the metal pins 50 to be rigidly fixed to the electrodes 30, and can improve conductivity of the cured product 40 of the conductive paste.

Further, such an alloy has excellent heat resistance and thus can also improve the heat resistance of the package substrate to be produced.

The term “viscosity” as used herein refers to the viscosity measured with a rheometer (model number: MCR302; manufacturer: Anton Parr) under the following conditions.

Heating rate: 5° C./min

### Measurement jig: PP25

### Amplitude y: 0.1%

### Frequency f: 1 Hz

### Temperature: 25° C. to 200° C.

The package substrate of the present invention can be produced by the above steps.

### (Second Exemplary Method of Producing the Package Substrate of the Present Invention)

The second exemplary method of producing the package substrate of the present invention includes:

(1) a substrate preparation step of preparing a substrate including an electrode disposed on a surface thereof;
(2) a conductive paste attaching step of attaching a conductive paste containing a metal powder and a thermosetting resin to an end of the metal pin;
(3) a metal pin positioning step of positioning the metal pin on the electrode by contact with the conductive paste; and
(4) a metal pin disposing step of disposing the metal pin on the electrode via a cured product of the conductive paste obtained by heating the conductive paste to soften and then cure the conductive paste.

Specifically, the second exemplary method of producing the package substrate of the present invention is the same as the method of producing the package substrate of the first exemplary method of producing the package substrate of the present invention, except that (2) printing step and (3) metal pin positioning step are replaced by (2′) conductive paste attaching step and (3′) metal pin positioning step, respectively.

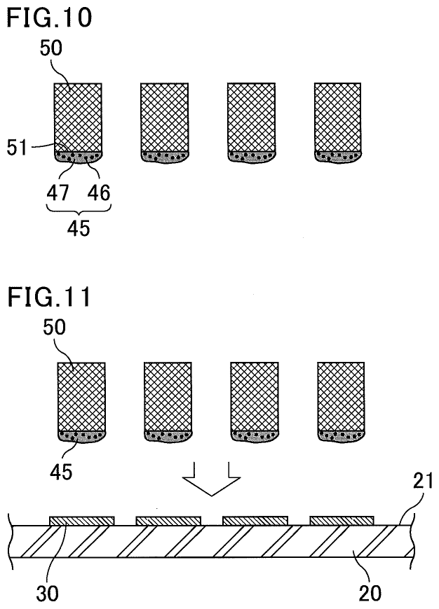

FIG. 10 is a schematic view showing a conductive paste attaching step included in the method of producing the package substrate of the present invention.

FIG. 11 is a schematic view showing a metal pin positioning step included in the method of producing the package substrate of the present invention.

### (2′) Conductive Paste Attaching Step

First, as described in “(2-1) Preparation of conductive paste”, a conductive paste containing a metal powder and a thermosetting resin is produced.

Next, in this step, as shown in FIG. 10, the conductive paste 45 containing the metal powder 46 and the thermosetting resin 47 is attached to an end 51 of each metal pin 50.

The method of attaching the conductive paste 45 to the metal pin 50 of each end 51 is not particularly limited. For example, a dipping method may be used.

Preferred shapes, materials, and the like of the metal pins 50 and preferred compositions of the conductive paste 45 are as described above, and the descriptions thereof are thus omitted.

### (3′) Metal Pin Positioning Step

In this step, as shown in FIG. 11, the metal pins 50 are positioned on the electrodes 30 by contact with the conductive paste 45 attached to the end 51 of each metal pin 50.

A preferred density of the metal pins 50 is as described above, and the description thereof is thus omitted.

### EXAMPLES

The present invention is described more specifically below with reference to examples, but the present invention is not limited to these examples.

### Example 1

### (1) Substrate Preparation Step

An epoxy resin substrate including copper electrodes disposed on a surface thereof was prepared.

### (2) Printing Step

### (2-1) Preparation of Conductive Paste

Raw materials were mixed at a ratio shown in Table 1, and stirred in a planetary mixer at 500 rpm for 30 minutes, whereby a conductive paste was prepared.

TABLE 1

| | | | | | | Comparative |
|---|---|---|---|---|---|---|
| Raw materials of the conductive paste | | | Example 1 | Example 2 | Example 3 | Example 1 |
| Thermosetting resin | | Bisphenol F epoxy resin | 4.3 | — | — | 4.3 |
| | | Aminophenol epoxy resin | — | 4.0 | 6.0 | — |
| | | 1,6-Hexanediol diglycidyl ether | 2.0 | 2.0 | 1.5 | 2.0 |
| Metal powder | High-melting | Silver-coated copper powder | 40.0 | 40.0 | — | — |
| | point metal | Silver powder | — | — | 50.5 | — |
| | Low-melting | Sn 42%—Bi 58% alloy | 51.7 | 52.0 | — | 91.7 |
| | point metal | Sn 80%—Bi 20% alloy | — | — | 40.0 | — |

| | | | | | |
|---|---|---|---|---|---|
| Curing agent | 2-Phenyl-4,5-dihydroxymethylimidazole | — | 0.5 | — | 0.5 |
| | 2-Phenylimidazole | 0.5 | — | 0.5 | — |
| Flux | Triethanolamine | 1.5 | 1.5 | 1.5 | 1.5 |

In Table 1, numerical values of the raw materials represent parts by weight.

In Table 1, the silver-coated copper powder has an average particle size of 2 μm, with the silver having a melting point of 962° C. and the copper having a melting point of 1085° C.

In Table 1, the silver powder has an average particle size of 5 μm and a melting point of 962° C.

In Table 1, the Sn 42%-Bi 58% alloy has an average particle size of 10 μm and a melting point of 139° C.

In Table 1, the Sn 80%-Bi 20% alloy has an average particle size of 5 μm and a melting point of 139° C.

### (2-2) Printing of Conductive Paste

The thus-obtained conductive paste was printed using a metal mask having multiple openings with a hole diameter of 100 μm and a thickness of 60 μm.

### (3) Metal Pin Positioning Step

Substantially cylindrical metal pins made of copper, each having a diameter of 150 μm and a height of 200 μm, were positioned on the conductive paste.

### (4) Metal Pin Disposing Step

The conductive paste was heated at 180° C. for one hour to soften and then cure the conductive paste into a cured product of the conductive paste.

Thus, the metal pins were disposed on the electrodes via the cured product of the conductive paste.

A package substrate according to Example 1 was produced by the above steps.

### (Example 2), (Example 3), and (Comparative Example 1)

Package substrates according to Example 2, Example 3, and Comparative Example 1 were produced as in Example 1, except that the raw materials of the conductive paste were changed according to Table 1.

### (Evaluation of Printability)

In “(2-2) Printing of conductive paste” in producing the package substrates according to Examples 1 to 3 and Comparative Example 1, the number of portions where the conductive paste was printed was visually counted to evaluate the printability.

The evaluation criteria are as follows. The transfer rate (%) was calculated by the following formula: (Number of portions where conductive paste was transferred to substrate through openings of metal mask)/(Total number of openings of metal mask)×100. Table 2 shows the evaluation results.

Good: The transfer rate is 100%.
Average: The transfer rate is less than 100% to 80%.
Poor: The transfer rate is less than 80%.

TABLE 2

| | | | | Comparative |
|---|---|---|---|---|
| | Example 1 | Example 2 | Example 3 | Example 1 |
| Evaluation of | Good | Good | Good | Good |
| printability | | | | |

### (Observation of Boundary Between Cured Product of Conductive Paste and Metal Pin)

The cured product of the conductive paste and the metal pin were taken out from the package substrate produced according to Example 1 such that a boundary between the cured product of the conductive paste and the metal pin was included.

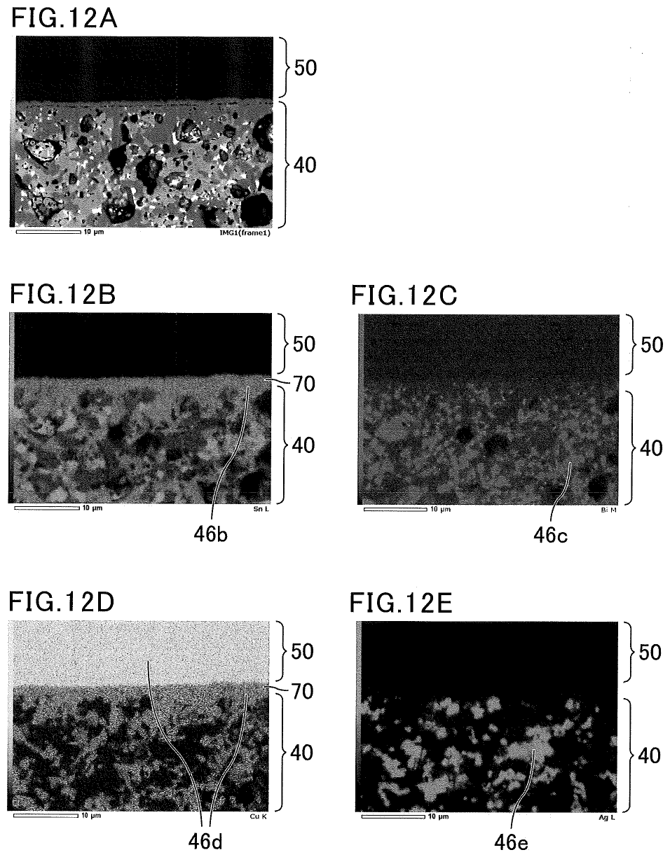

The cured product of the conductive paste and the metal pin were cut such that the boundary between the cured product of the conductive paste and the metal pin was exposed on the cut surface. Then, the cut surface was observed using a scanning electron microscope (SEM), and elements such as tin, bismuth, copper, and silver on the cut surface were analyzed by EDS to map the distribution of these elements. FIGS. 12A to 12E show the results.

FIG. 12A is an SEM image of the boundary between the cured product of the conductive paste and the metal pin on the package substrate according to Example 1.

FIG. 12B is a mapping image showing the distribution of tin on the boundary between the cured product of the conductive paste and the metal pin on the package substrate according to Example 1.

FIG. 12C is a mapping image showing the distribution of bismuth on the boundary between the cured product of the conductive paste and the metal pin on the package substrate according to Example 1.

FIG. 12D is a mapping image showing the distribution of copper on the boundary between the cured product of the conductive paste and the metal pin on the package substrate according to Example 1.

FIG. 12E is a mapping image showing the distribution of silver on the boundary between the cured product of the conductive paste and the metal pin on the package substrate according to Example 1.

In FIGS. 12A to 12E, a reference sign 40 indicates a cured product portion of the conductive paste, and a reference sign 50 indicates a metal pin portion.

In FIGS. 12B to 12E, reference signs 46b, 46c, 46d, and 46e indicate sites where tin, bismuth, copper, and silver are distributed, respectively.

In FIGS. 12B and 12D, a reference sign 70 indicates an alloy of tin and copper.

As shown in FIGS. 12B and 12D, an alloy of tin and copper was present between the cured product of the conductive paste and the metal pin. In other words, a part of the cured product of the conductive paste was integrated with a part of the metal pin.

Thus, in the package substrate of Example 1, the metal pins were rigidly fixed to the electrodes.

### (Observation of Tilting of Metal Pins)

Tilting of the metal pins on the package substrates produced according to Examples 1 to 3 and Comparative Example 1 was visually observed and evaluated.

The evaluation criteria are as follows. Table 3 shows the results.

Excellent: The percentage of tilting metal pins is less than 5%.
Good: The percentage of tilting metal pins is 5 to 10%.
Poor: The percentage of tilting metal pins is more than 10%.

TABLE 3

| | | | | Comparative |
|---|---|---|---|---|
| | Example 1 | Example 2 | Example 3 | Example 1 |
| Observation of tilting | Excellent | Excellent | Excellent | Poor |
| of metal pins | | | | |

These results show that the metal pins are less likely to tilt in the package substrates according to Examples 1 to 3 and these package substrates are suitable for stacking.

### REFERENCE SIGNS LIST

1, 101 PoP structure
10, 110 package substrate
20, 120 substrate
21, 121 surface of substrate
30, 31, 130, 131 electrode
40 cured product of conductive paste
45 conductive paste
46 metal powder
47 thermosetting resin
50, 150 metal pin
51 end of metal pin
70 alloy
160 solder ball
161 solder

1. A package substrate comprising:
a substrate; and
an electrode disposed on a surface of the substrate,
wherein a metal pin is disposed on the electrode via a cured product of a conductive paste containing a metal powder and a thermosetting resin, and
the metal powder contains a low-melting point metal and a high-melting point metal having a melting point higher than that of the low-melting point metal.

2. The package substrate according to claim 1, wherein an alloy of the low-melting point metal and the metal pin is present between the cured product of the conductive paste and the metal pin.

3. The package substrate according to claim 1, wherein the low-melting point metal has a melting point of 180° C. or lower.

4. The package substrate according to claim 1, wherein the low-melting point metal includes at least one selected from the group consisting of indium, tin, lead, and bismuth.

5. The package substrate according to claim 1, wherein the high-melting point metal has a melting point of 800° C. or higher.

6. The package substrate according to claim 1, wherein the high-melting point metal includes at least one selected from the group consisting of copper, silver, gold, nickel, silver-coated copper, and silver-coated copper alloy.

7. The package substrate according to claim 1, wherein the metal pin includes at least one selected from the group consisting of copper, silver, gold, and nickel.

8. A method of producing the package substrate according to claim 1, comprising:
a substrate preparation step of preparing a substrate including an electrode disposed on a surface thereof;
a printing step of printing a conductive paste containing a metal powder and a thermosetting resin on the electrode;
a metal pin positioning step of positioning a metal pin on the conductive paste; and
a metal pin disposing step of disposing the metal pin on the electrode via a cured product of the conductive paste obtained by heating the conductive paste to soften and then cure the conductive paste,
wherein the metal powder contains a low-melting point metal and a high-melting point metal having a melting point higher than that of the low-melting point metal.

9. A method of producing the package substrate according to claim 1, comprising:
a substrate preparation step of preparing a substrate including an electrode disposed on a surface thereof;
a conductive paste attaching step of attaching a conductive paste containing a metal powder and a thermosetting resin to an end of a metal pin;
a metal pin positioning step of positioning the metal pin on the electrode by contact with the conductive paste; and
a metal pin disposing step of disposing the metal pin on the electrode via a cured product of the conductive paste obtained by heating the conductive paste to soften and then cure the conductive paste,
wherein the metal powder contains a low-melting point metal and a high-melting point metal having a melting point higher than that of the low-melting point metal.
